(19) United States
(12) Patent Application Publication
(10) Pub. No.: US 2017/0077263 A1
(43) Pub. Date: Mar. 16, 2017

(54) METHOD OF MANUFACTURING SEMICONDUCTOR DEVICE

(71) Applicant: Toyota Jidosha Kabushiki Kaisha, Toyota-shi (JP)

(72) Inventor: Yuta Furumura, Nagakute-shi (JP)

(21) Appl. No.: 15/255,615

(22) Filed: Sep. 2, 2016

(30) Foreign Application Priority Data
Sep. 11, 2015 (JP) 2015-179534

(51) Int. Cl. H01L 29/66; H01L 21/266; H01L 21/324; H01L 29/06; H01L 21/265; H01L 21/268

(52) U.S. Cl. CPC H01L 29/66333; H01L 21/26513; H01L 21/268; H01L 21/324; H01L 29/0696; H01L 21/266; H01L 29/6609

(57) ABSTRACT

A manufacturing method includes an implantation of impurities and laser irradiation. In the implantation, impurities are implanted to first and second areas so as to obtain a relationship that a total amount of the first impurities is larger than a total amount of the second impurities in a first depth range and a total amount of the second impurities is larger than a total amount of the first impurities in a second depth range (deeper range). In the irradiation, the first and second areas are irradiated with laser so that an energy density of the laser is larger on the second area than on the first area. A first conductivity type region is formed on the first area so as to be exposed on the surface, and a second conductivity type region is formed on the second area so as to be exposed on the surface.

### CROSS-REFERENCE TO RELATED APPLICATION

This application claims priority to Japanese Patent Application No. 2015-179534 filed on Sep. 11, 2015, the entire contents of which are hereby incorporated by reference into the present application.

### TECHNICAL FIELD

The art disclosed herein relates to a method of manufacturing a semiconductor device.

### DESCRIPTION OF RELATED ART

Japanese Patent Application Publication No. 2013-197122 discloses a semiconductor device that includes an Insulated Gate Biploar Transistor (IGBT) and a diode in a single semiconductor substrate (also known as a Reverse Conducting (RC)-IGBT). In this RC-IGBT, an n-type cathode region and a p-type collector region (which is referred to as a drain region in Japanese Patent Application Publication No. 2013-197122) are disposed so as to be exposed on a lower surface of a semiconductor substrate. In a step of manufacturing this semiconductor device, a first resist mask is formed on the lower surface of the semiconductor substrate. The first resist mask covers an area where the cathode region is to be formed. In the first resist mask, an opening is provided in an area where the collector region is to be formed. Next, p-type impurities are implanted to the semiconductor substrate via the first resist mask, consequently, the p-type collector region is formed. Subsequently, the first resist mask is removed and a second resist mask is newly formed. The second resist mask covers the collector region. In the second resist mask, an opening is provided in the area where the cathode region is to be formed. Subsequently, n-type impurities are implanted to the semiconductor substrate via the second resist mask, and consequently the n-type cathode region is formed.

### BRIEF SUMMARY

As mentioned above, in the art in Japanese Patent Application Publication No. 2013-197122, by implanting impurities to the semiconductor substrate via the first and second resist masks, the n-type cathode region and the p-type collector region are formed separately. In this method, to form each of the resist masks, steps of forming a resist film, exposing the resist film to light, etching (patterning) the resist film, cleaning the semiconductor substrate, and the like are required. Moreover, to remove the used resist masks, steps of etching the resist masks, cleaning the semiconductor substrate, and the like are required. As such, if the resist masks are used to delimit an area to implant n-type impurities and an area to implant p-type impurities, a large number of steps are required, which makes it difficult to efficiently manufacture a semiconductor device. Notably, this problem occurs not only in the steps of manufacturing an RC-IGBT, but also commonly in cases of forming an n-type region and a p-type region both exposed on a surface of a semiconductor substrate. Accordingly, the present disclosure provides one or more embodiments by which an n-type region and a p-type region both exposed on a surface of a semiconductor substrate can be easily formed.

A method of manufacturing a semiconductor device disclosed herein comprises an implantation of impurities and laser irradiation. In the implantation, at least one of first impurities of a first conductivity type and second impurities of a second conductivity type is implanted into a processing area in a surface of a semiconductor substrate. The processing area includes a first area in the surface and a second area in the surface. The implantation is performed so as to obtain, in an impurity distribution along a depth direction of the semiconductor substrate, a relationship that a total amount of the first impurities is larger than a total amount of the second impurities in a first depth range between the surface and a first position and a total amount of the second impurities is larger than a total amount of the first impurities in a second depth range between the surface and a second position. The first position is located at a first depth from the surface, the second position is located at a second depth from the surface, and the second depth is deeper than the first depth. In the laser irradiation, the surface is irradiated with a laser so that an energy density of the laser on the second area is larger than an energy density of the laser on the first area. A first conductivity type region in which the first impurities exist in higher density than the second impurities is formed in the first depth range on the first area so as to be exposed on the surface. A second conductivity type region in which the second impurities exist in higher density than the first impurities is formed in the second depth range on the second area so as to be exposed on the surface.

Notably, a total amount of the impurities in the view of the impurity density distribution in the depth direction corresponds to a value obtained by integrating the impurity density in the depth direction. Moreover, the energy density means a value obtained by integrating, by time, an intensity of the laser with which the surface of the semiconductor substrate is irradiated with the laser. For example, in a case of laser irradiation having an irradiation intensity of A1 (W/cm²) to an area for t1 seconds, it is meant that the laser irradiation onto the irradiated area has an energy density of A1t1 (J/cm²).

In this manufacturing method, the first and second areas of the surface of the semiconductor substrate are irradiated with a laser during the laser irradiation. The first area is irradiated with the laser at a low energy density, and hence a shallow portion in a proximity of the surface of the semiconductor substrate (i.e., the semiconductor region in the first depth range) is heated. On the other hand, the second area is irradiated with the laser at a high energy density, and hence the semiconductor region ranging from the surface of the semiconductor substrate to a deep portion thereof is heated. In other words, on the second area, the semiconductor region in a wide depth range ranging from the shallow portion to the deep portion of the semiconductor substrate (i.e., the semiconductor region in the second depth range (which may hereinafter be referred to as a wide semiconductor region in the depth direction)) is heated. The impurities are diffused in the heated semiconductor regions (the semiconductor region in the shallow portion on the first area, and the wide semiconductor region in the depth direction on the second area). Due to the diffusion of the impurities, the impurity density distribution in each of the heated semiconductor regions comes to be more uniformized, compared with the impurity density distribution prior to the heating.

Prior to the laser irradiation, the total amount of the first impurities is larger than the total amount of the second impurities in the semiconductor region in the shallow portion (the first depth range). Therefore, when the impurities are diffused in the semiconductor region in the shallow portion in the laser irradiation, the first impurity density becomes higher than the second impurity density in a substantial entirety of the semiconductor region in the shallow portion. Accordingly, on the first area, the first conductivity type region is formed in the first depth range so as to be exposed on the surface of the semiconductor substrate.

On the other hand, prior to the laser irradiation, the total amount of the second impurities is larger than the total amount of the first impurities in the wide semiconductor region in the depth direction (the semiconductor region in the second depth range). Therefore, when the impurities are diffused in the wide semiconductor region in the depth direction in the laser irradiation, a large amount of the second impurities move from the deep portion to the shallow portion. Consequently, the second impurity density becomes higher than the first impurity density in a substantial entirety of the wide semiconductor region in the depth direction. Accordingly, on the second area, the second conductivity type region is formed in the second depth range so as to be exposed on the surface of the semiconductor substrate.

As described above, according to this method, only by implanting impurities so that predetermined density distribution in the depth direction can be obtained, and then by performing laser irradiation so that the energy density changes depending on positions, it is possible to form the first conductivity type region and the second conductivity type region so as to be exposed on the surface of the semiconductor substrate. Therefore, there is no need to form resist masks for delimiting areas where impurities are to be implanted. Moreover, it is easy to irradiate the laser to different areas at different energy densities. Therefore, according to this method, the semiconductor device can be manufactured efficiently.

### BRIEF DESCRIPTION OF THE DRAWINGS

FIG. 1 is a vertical cross-sectional view of a semiconductor device 10;

FIG. 2 is a graph that shows impurity density distributions at a position on a line II-II in FIG. 1;

FIG. 3 is a graph that shows impurity density distributions at a position on a line in FIG. 1;

FIG. 4 is a vertical cross-sectional view that shows a manufacturing process of the semiconductor device 10;

FIG. 5 is a vertical cross-sectional view that shows the manufacturing process of the semiconductor device 10;

FIG. 6 is a graph that shows impurity density distributions at the positions in FIGS. 2 and 3 prior to a laser irradiation step; and

FIG. 7 is an explanatory view of the laser irradiation step.

### DETAILED DESCRIPTION

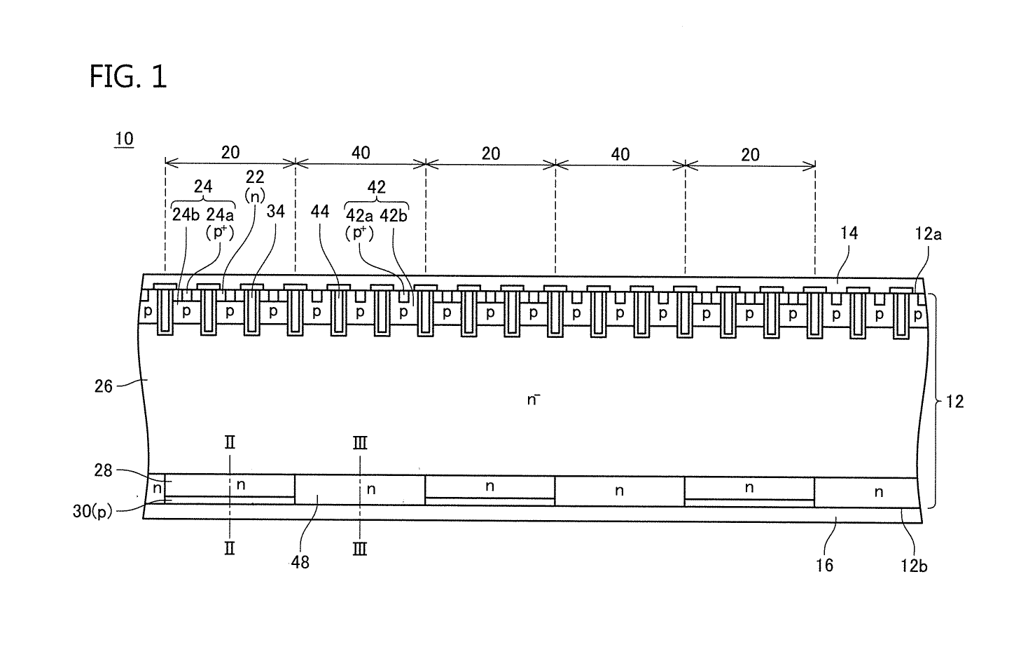

A semiconductor device 10 in an embodiment shown in FIG. 1 comprises a semiconductor substrate 12, an upper electrode 14, and a lower electrode 16. The semiconductor substrate 12 is a substrate made of silicon. The upper electrode 14 is provided on an upper surface 12a of the semiconductor substrate 12. The lower electrode 16 is provided on a lower surface 12b of the semiconductor substrate 12.

The semiconductor substrate 12 comprises a plurality of IGBT regions 20 comprising vertical IGBT therein, and a plurality of diode regions 40 comprising vertical diode therein. The IGBT regions 20 and the diode regions 40 are provided so as to be arranged alternately and repeatedly in one direction parallel to the upper surface 12a of the semiconductor substrate 12. The upper electrode 14 serves as both of an emitter electrode of the IGBT and an anode electrode of the diode. The lower electrode 16 serves as both of a collector electrode of the IGBT and a cathode electrode of the diode.

Emitter regions 22, a body region 24, a drift region 26, a buffer region 28, and a collector region 30 are provided in the semiconductor substrate 12 in each of the IGBT regions 20.

The emitter regions 22 are an n-type region and are disposed so as to be exposed on the upper surface 12a of the semiconductor substrate 12. The emitter regions 22 are in ohmic contact with the upper electrode 14.

Each body region 24 is a p-type region and is in contact with the emitter regions 22. The body region 24 is disposed so as to be exposed on the upper surface 12a of the semiconductor substrate 12. The body region 24 extends from lateral sides of the emitter regions 22 to undersides of the emitter regions 22. The body region 24 has body contact regions 24a and a low density body region 24b. The body contact regions 24a have a high p-type impurity density. The body contact regions 24a are disposed so as to be exposed on the upper surface 12a of the semiconductor substrate 12 and in ohmic contact with the upper electrode 14. The low density body region 24b has a lower p-type impurity density than the body contact regions 24a. The low density body region 24b is disposed on the undersides of the emitter regions 22 and undersides of the body contact regions 24a.

The drift region 26 is an n-type region and in contact with the body regions 24. The drift region 26 is disposed on an underside of the body regions 24. The drift region 26 is separated from the emitter regions 22 by the body regions 24.

The buffer regions 28 are an n-type region and in contact with the drift region 26. The buffer regions 28 are disposed on an underside of the drift region 26. An n-type impurity density in the buffer regions 28 is higher than an n-type impurity density in the drift region 26.

The collector regions 30 are a p-type region and each of them is in contact with the corresponding buffer region 28. The collector region 30 is disposed on an underside of the buffer region 28. The collector regions 30 are disposed so as to be exposed on the lower surface 12b of the semiconductor substrate 12. The collector regions 30 are in ohmic contact with the lower electrode 16. The collector regions 30 are separated from the body regions 24 by the drift region 26 and the buffer regions 28.

A plurality of trenches is provided in the upper surface 12a of the semiconductor substrate 12 in each of the IGBT regions 20. Each of the trenches is disposed at a position adjacent to the corresponding emitter region 22. Each of the trenches penetrates the body region 24 and reaches the drift region 26.

An inner surface of each of the trenches in the IGBT regions 20 is covered with a gate insulating film. Moreover, a gate electrode 34 is disposed in each of the trenches. Each gate electrode 34 is insulated from the semiconductor substrate 12 by the corresponding gate insulating film. Each gate electrode 34 faces the corresponding emitter region 22, the corresponding low density body region 24b, and the drift region 26 via the gate insulating film. An interlayer insulating film is disposed on a top of each gate electrode 34. Each gate electrode 34 is insulated from the upper electrode 14 by the interlayer insulating film.

An anode region 42, the drift region 26, and a cathode region 48 are disposed in the semiconductor substrate 12 in each of the diode regions 40.

Each anode region 42 is disposed so as to be exposed on the upper surface 12a of the semiconductor substrate 12. The anode region 42 comprises anode contact regions 42a and a low density anode region 42b. The anode contact regions 42a have a high p-type impurity density. The anode contact regions 42a are disposed so as to be exposed on the upper surface 12a of the semiconductor substrate 12, and in ohmic contact with the upper electrode 14. The low density anode region 42b has a lower p-type impurity density than the anode contact regions 42a. The low density anode region 42b is disposed on lateral sides and undersides of the anode contact regions 42a.

In each of the diode regions 40, the drift region 26 is disposed on undersides of the anode regions 42. The drift region 26 is in contact with the anode regions 42.

The cathode regions 48 are an n-type region and in contact with the drift region 26. The cathode regions 48 are disposed on the underside of the drift region 26. An n-type impurity density in the cathode regions 48 is higher than the n-type impurity density in the drift region 26. The cathode regions 48 are disposed so as to be exposed on the lower surface 12b of the semiconductor substrate 12. The cathode regions 48 are in ohmic contact with the lower electrode 16.

A plurality of trenches is provided in the upper surface 12a of the semiconductor substrate 12 in each of the diode regions 40. Each of the trenches penetrates the corresponding anode region 42 and reaches the drift region 26.

An inner surface of each of the trenches in the diode regions 40 is covered with an insulating film. Moreover, a control electrode 44 is disposed in each of the trenches. Each control electrode 44 is insulated from the semiconductor substrate 12 by the corresponding insulating film. Each control electrode 44 faces the corresponding anode region 42 and the drift region 26 via the insulating film. An interlayer insulating film is disposed on a top of the control electrode 44. Each control electrode 44 is insulated from the upper electrode 14 by the corresponding interlayer insulating film.

As mentioned above, the p-type collector regions 30 are disposed so as to be exposed on the lower surface 12b of the semiconductor substrate 12 in the IGBT regions 20, and the n-type cathode regions 48 are disposed so as to be exposed on the lower surface 12b of the semiconductor substrate 12 in the diode regions 40. Accordingly, the p-type collector regions 30 and the n-type cathode regions 48 are exposed on the lower surface 12b of the semiconductor substrate 12. As seen along one direction parallel to the lower surface 12b of the semiconductor substrate 12, exposed areas of the collector regions 30 and exposed areas of the cathode regions 48 are disposed alternately and repeatedly.

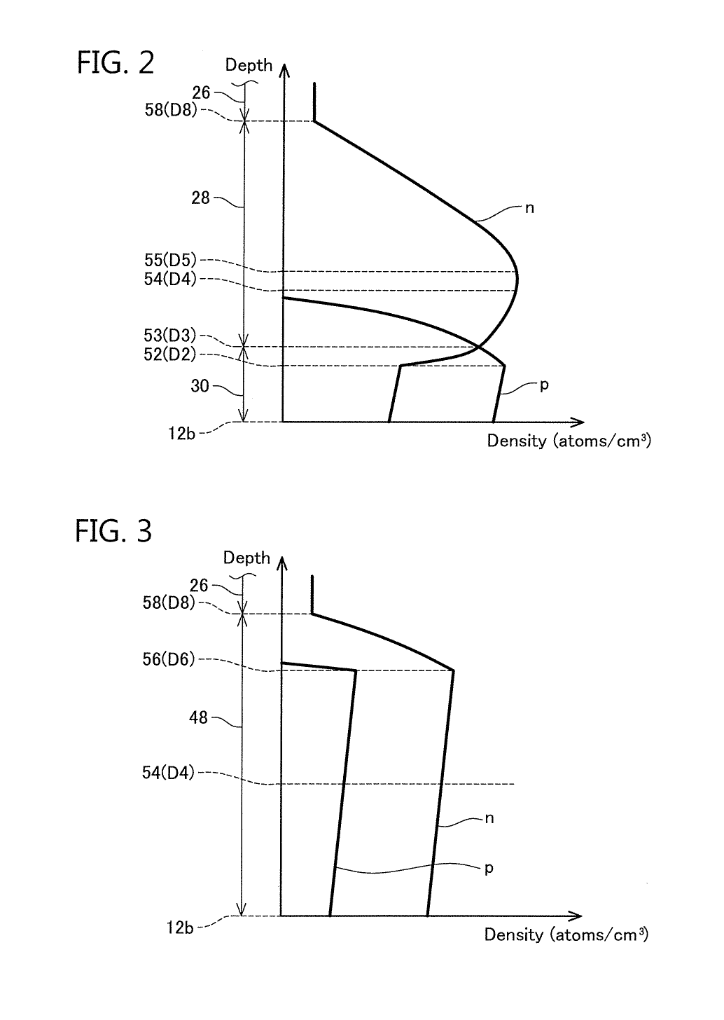

FIG. 2 shows impurity density distributions at a position on a line II-II in FIG. 1 (i.e., impurity density distributions in the collector region 30 and the buffer region 28 along a depth direction). A vertical axis in FIG. 2 represents a depth from the lower surface 12b of the semiconductor substrate 12. An origin in FIG. 2 (i.e., the depth being zero) represents the position of the lower surface 12b.

In a depth range between the lower surface 12b and a position 53 of a depth D3, the p-type impurity density is higher than the n-type impurity density. In other words, in the depth range between the lower surface 12b and the position 53, the p-type collector region 30 is disposed. Moreover, in a portion of the collector region 30 except for its deepest portion (i.e., a depth range between a position 52 of a depth D2 (a depth shallower than the depth D3) and the lower surface 12b), the p-type impurity density is distributed at an approximately constant level, and the n-type impurity density is distributed at an approximately constant level that is lower than that of the p-type impurity density. In the deepest portion in the collector region 30 (i.e., a depth range between the position 52 and the position 53), the p-type impurity density drastically decreases as the depth becomes deeper, while the n-type impurity density drastically increases as the depth becomes deeper. At the position 53, the p-type impurity density and the n-type impurity density coincide with each other.

On a side deeper than the position 53, the p-type impurity density is further decreases. Accordingly, on the side deeper than the position 53, the n-type impurity density is higher than the p-type impurity density. In a depth range between the position 53 of the depth D3 and a position 58 of a depth D8 (a depth deeper than the depth D3), the n-type impurity density is relatively high. On a side deeper than the position 58, the n-type impurity density is distributed at an approximately constant level that is extremely low. The semiconductor region on the side deeper than the position 58 is the drift region 26 that has a low n-type impurity density. The semiconductor region between the position 53 and the position 58 is the buffer region 28 that has a higher n-type impurity density than the drift region 26. A peak of the n-type impurity density is at a position 55 of a depth D5 in the buffer region 28. In the buffer region 28, the n-type impurity density is normally distributed, with the peak at the position 55 being centered.

FIG. 3 shows impurity density distributions at a position on a line in FIG. 1 (i.e., impurity density distributions in the cathode region 48 along the depth direction). Depths D4 and D8 in FIG. 3 approximately coincide with a depth D4 and the depth D8 in FIG. 2, respectively.

In the diode region 40, the n-type impurity density is higher than the p-type impurity density in an approximately entire region in the proximity of the lower surface 12b. In a depth range between the lower surface 12b and the position 58, the n-type impurity density is relatively high. On the side deeper than the position 58, the n-type impurity density is distributed at an approximately constant level that is extremely low. The semiconductor region on the side deeper than the position 58 is the drift region 26 that has a low n-type impurity density. The semiconductor region between the lower surface 12b and the position 58 is the cathode region 48 that has a higher n-type impurity density than the drift region 26. Moreover, in a portion in the cathode region 48 except for its deepest portion (i.e., a depth range between the lower surface 12b and a position 56 of a depth D6 (a depth shallower than the depth D8), the n-type impurity density is distributed at an approximately constant level, and the p-type impurity density is distributed at an approximately constant level that is lower than that of the n-type impurity density. In the deepest portion in the cathode region 48 (i.e., a depth range between the position 56 and the position 58), the n-type impurity density drastically decreases as the depth becomes deeper.

Next, an operation of the IGBT will be described. When the IGBT is to be turned on, a potential of the gate electrodes 34 is raised to a threshold value or higher. A channel is thereby formed in each body region 24 in the proximity of the respective gate insulating films. In this state, when a potential of the lower electrode 16 is raised to a potential higher than that of the upper electrode 14, a current flows from the lower electrode 16 to the upper electrode 14 through the IGBT regions 20. When the potential of the gate electrodes 34 is lowered to a potential smaller than the threshold value, the channel disappears and the IGBT is turned off. In this state, a depletion layer extends downward from a pn junction at an interface between the p-type regions on the upper surface side (i.e., the body regions 24 and the anode regions 42) and the drift region 26. When the depletion layer reaches the buffer regions 28 and the cathode regions 48 each having a high n-type impurity density, the extension of the depletion layer stops. The depletion layer is thereby prevented from reaching the lower surface 12b (i.e., a so-called punch-through is prevented).

Next, an operation of the diode will be described. When the potential of the upper electrode 14 is raised to a potential higher than that of the lower electrode 16, a forward voltage is applied to the pn junction at each interface between the anode regions 42 and the drift region 26. The diode is thereby turned on and a current flows from the upper electrode 14 to the lower electrode 16 through the diode regions 40. Moreover, a forward voltage is also applied to the pn junction at each interface between the body regions 24 and the drift region 26 in the IGBT regions 20. Accordingly, a current also flows from the upper electrode 14 to the lower electrode 16 through paths between these pn junctions and the cathode regions 48. Afterwards, when the potential of the upper electrode 14 is lowered to a potential lower than that of the lower electrode 16, the diode performs a reverse recovery operation. In the reverse recovery operation, holes that exist in the drift region 26 are discharged into the upper electrode 14 via the anode regions 42 and the body regions 24, and electrons that exist in the drift region 26 are discharged into the lower electrode 16 via the cathode regions 48. Accordingly, a high reverse current (a so-called reverse recovery current) instantaneously flows through the semiconductor device 10.

When the n-type cathode regions 48 as well as the p-type collector regions 30 are disposed so as to be exposed on the lower surface 12b as in the semiconductor device 10, an amount of electrons that flow from the lower electrode 16 into the drift region 26 while the diode is on becomes less. Therefore, an amount of electrons discharged from the drift region 26 into the lower electrode 16 during the reverse recovery operation also becomes less. According to this structure, a reverse recovery current in the diode can be suppressed. Accordingly, a loss during the reverse recovery operation in the diode can be suppressed.

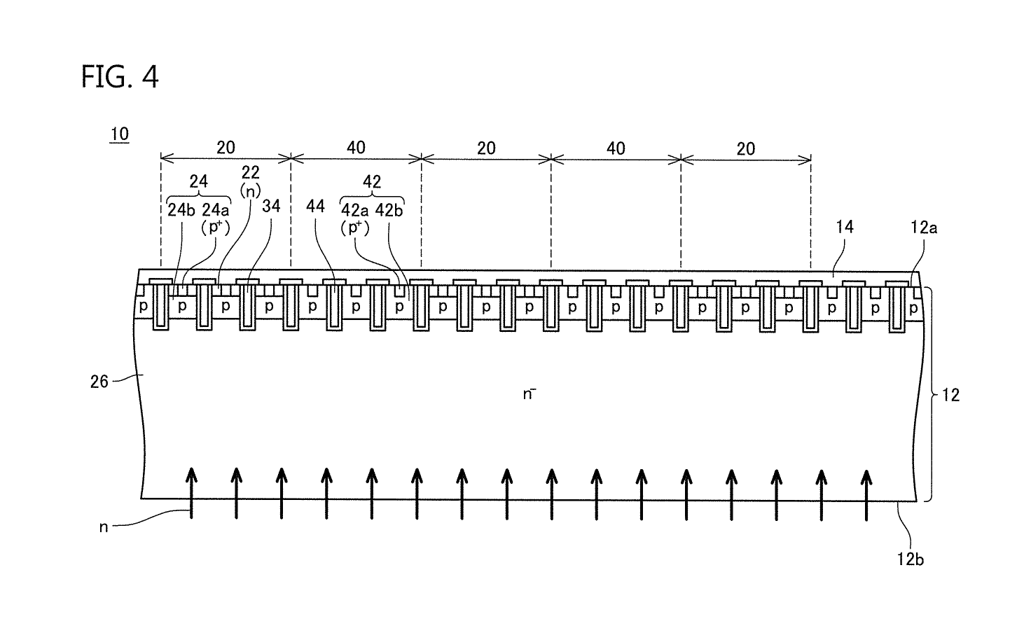

Next, a method of manufacturing the semiconductor device 10 will be described. Initially, as shown in FIG. 4, a structure on the upper surface 12a side of the semiconductor device 10 is formed by a conventionally-known method. At this stage, the drift region 26 is exposed on an entirety of the lower surface 12b.

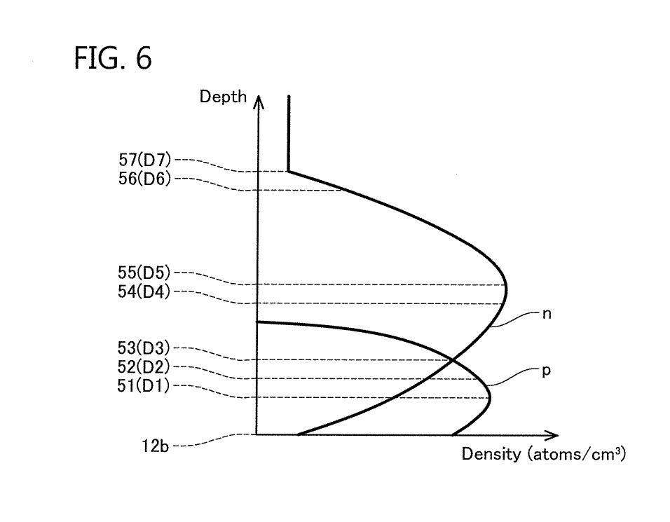

Next, an n-type impurity implantation step is performed. Here, as shown in FIG. 4, n-type impurities are implanted to the entirety of the lower surface 12b of the semiconductor substrate 12. Here, as shown in FIG. 6, the n-type impurities are implanted so that a peak of the n-type impurity density is at the position 55 of the depth D5. Performing the n-type impurity implantation step causes the n-type impurity density to be normally distributed in a depth range between the lower surface 12b and a position 57 (a position of a depth D7), with the position 55 being centered in its distribution.

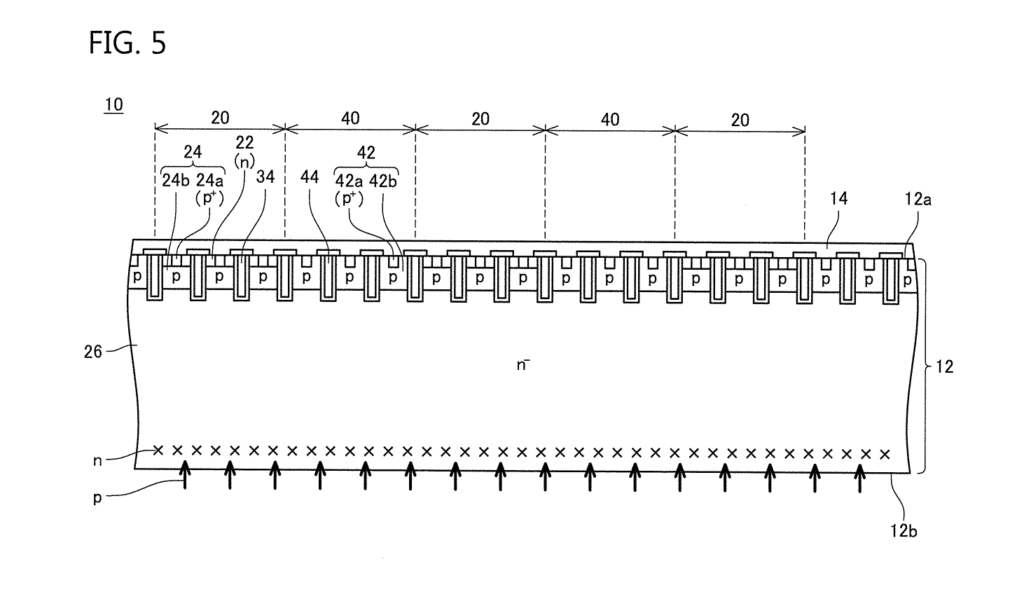

Next, a p-type impurity implantation step is performed. Here, as shown in FIG. 5, p-type impurities are implanted to the entirety of the lower surface 12b of the semiconductor substrate 12. Here, as shown in FIG. 6, the p-type impurities are implanted so that a peak of the p-type impurity density is at a position 51 of a depth D1 (a depth shallower than the depth D5). Performing the p-type impurity implantation step causes the p-type impurity density to be normally distributed, with the position 51 being centered in its distribution. Notably, a dose (atoms/cm²) of the p-type impurities in the p-type impurity implantation step is smaller than a dose of the n-type impurities in the n-type impurity implantation step. Here, the dose means a total amount of impurities implanted to a unit area of the lower surface 12b. Moreover, the p-type impurity implantation step may be performed prior to the n-type impurity implantation step.

As mentioned above, after the n-type impurity implantation step and the p-type impurity implantation step are performed, the impurity density distributions shown in FIG. 6 are obtained. Notably, the depths D2, D3, D4, D5, and D6 in FIG. 6 approximately coincide with the depths D2, D3, D4, D5, and D6 in FIGS. 2 and 3, respectively. Moreover, at this stage, both in the IGBT regions 20 (i.e., at the position on the line II-II in FIG. 1) and in the diode regions 40 (i.e., at the position on the line in FIG. 1), the impurity densities are distributed as shown in FIG. 6. As mentioned above, the peak of the p-type impurities is at the position 51 of the depth D1, and the peak of the n-type impurities is at the position 55 of the depth D5 which is deeper than the depth D1. At the position 53 of the depth D3 which is located between the depth D1 and the depth D5, the p-type impurity density and the n-type impurity density approximately coincide with each other. In a depth range in the proximity of the lower surface 12b which includes the position 51 having the peak of the p-type impurity density (i.e., the depth range between the lower surface 12b and the position 53), the p-type impurity density is higher than the n-type impurity density. In a depth range that includes the position 55 having the peak of the n-type impurity density, (i.e., a range deeper than the position 53), the n-type impurity density is higher than the p-type impurity density.

Moreover, as mentioned above, the dose of the p-type impurities is smaller than the dose of the n-type impurities. A value obtained by integrating the p-type impurity density in FIG. 6 in an entire region in the depth direction corresponds to the dose of the p-type impurities, and a value obtained by integrating the n-type impurity density in FIG. 6 in the depth range between the lower surface 12b and the position 57 in the depth direction corresponds to the dose of the n-type impurities. Accordingly, in FIG. 6, the area of the graph of the p-type impurity density is smaller than the area of the graph of the n-type impurity density. Moreover, a position 54 of the depth D4 in FIG. 6 indicates a position at which the total amount of the p-type impurities that exist in a depth range between the lower surface 12b and the position 54 is equal to the total amount of the n-type impurities that exist in the depth range between the lower surface 12b and the position 54. In other words, the area (square measure) of the graph of the p-type impurity density in the depth range between the lower surface 12b and the position 54 is equal to the area (square measure) of the graph of the n-type impurity density in the depth range between the lower surface 12b and the position 54. Notably, although the depth D4 is shallower than the depth D5 in the present embodiment, the depth D4 may be deeper than the depth D5.

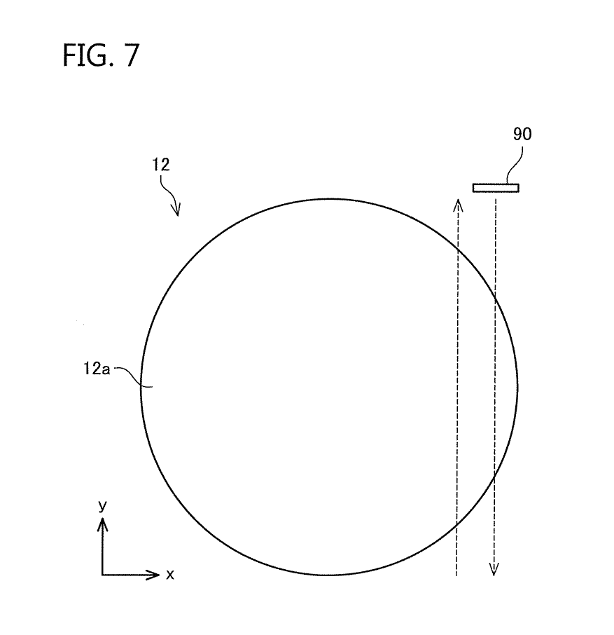

After the p-type impurities and the n-type impurities are implanted to obtain the distributions in FIG. 6, a laser irradiation step is performed. Here, laser is irradiated onto the lower surface 12b of the semiconductor substrate 12 to heat the semiconductor substrate 12. In the laser irradiation step, as shown in FIG. 7, a laser that has a rectangular focus 90 is used. As shown by arrows in FIG. 7, the focus 90, while being reciprocated along a y direction (one direction parallel to the lower surface 12b) on the lower surface 12b of the semiconductor substrate 12, is moved in an x direction (a direction parallel to the lower surface 12b and orthogonal to the y direction). The entirety of the lower surface 12b is thereby irradiated with the laser, and the semiconductor region in the proximity of the lower surface 12b is heated. When the focus 90 is reciprocated in the y direction, an area irradiated on a forward path and an area irradiated on a return path are partially overlapped. An energy density of the laser becomes high in the portion where areas irradiated on the forward path and the return path are overlapped, whereas the energy density of the laser becomes low in a portion where the areas irradiated on the forward path and the return path are not overlapped. Here, an irradiation path of the laser is set so that the energy density becomes low in the IGBT regions 20 and high in the diode regions 40.

In the IGBT regions 20, the energy density of the laser is low, and hence the semiconductor region in a shallow portion in the proximity of the lower surface 12b is heated. More specifically, a range up to the depth D2 shown in FIG. 6 (the depth shallower than the depths D3 and D4) (i.e., the depth range between the lower surface 12b and the position 52) is heated to a temperature equal to or higher than a melting point of silicon. Therefore, the semiconductor region in the depth range between the lower surface 12b and the position 52 is melted, and then that semiconductor region is solidified. When the semiconductor region is melted, the impurities are dispersed approximately uniformly in the melted semiconductor region. Accordingly, as shown in FIG. 2, after the heating, each of the p-type impurity density and the n-type impurity density becomes approximately constant in the depth range between the lower surface 12b and the position 52. Moreover, as shown in FIG. 6, prior to the heating, the total amount of the p-type impurities is larger than the total amount of the n-type impurities in the depth range between the lower surface 12b and the position 52. Accordingly, as shown in FIG. 2, after the heating, the p-type impurity density becomes higher than the n-type impurity density in an entirety of the depth range between the lower surface 12b and the position 52. The impurities are activated in the melted semiconductor regions. Accordingly, an activated p-type region is formed in the depth range between the lower surface 12b and the position 52. Moreover, the semiconductor region which is located deeper than the position 52 and is not melted is also heated by the laser. Therefore, in a range deeper than the position 52, the impurities are diffused in solid silicon. In a depth range adjacent to the melted range (i.e., a depth range between the position 52 and the position 53), the p-type impurity density is maintained higher than the n-type impurity density even after the heating. Moreover, the impurities are activated by the heating even in this depth range, and a p-type region is formed. Accordingly, in each IGBT region 20, the p-type collector region 30 exposed on the lower surface 12b is formed in the depth range between the lower surface 12b and the position 53. In the range deeper than the position 53, the n-type impurity density is maintained higher than the p-type impurity density even after the heating. It should be noted that the distribution range of the n-type impurities becomes somewhat wider due to the diffusion. Therefore, a position of an end on a deeper side of the distribution range of the n-type impurities shifts from the position 57 of the depth D7 (see FIG. 6) to the position 58 of the depth D8 (see FIG. 2), which is deeper than the depth D7. Moreover, the impurities are activated by the heating even in a depth range between the position 53 and the position 58. Accordingly, in each IGBT region 20, the n-type buffer region 28 is formed in a region deeper than the collector region 30 (in the depth range between the position 53 and the position 58).

In each diode region 40, the energy density of the laser is high, and hence the semiconductor region in the proximity of the lower surface 12b is heated from its shallow portion to deep portion. More specifically, the range up to the depth D6 shown in FIG. 6 (the depth deeper than the depths D4 and D5) (i.e., the depth range between the lower surface 12b and the position 56) is heated to a temperature equal to or higher than the melting point of silicon. Therefore, the semiconductor region in the depth range between the lower surface 12b and the position 56 is melted, and then that semiconductor region is solidified. Accordingly, as shown in FIG. 3, after the heating, each of the p-type impurity density and the n-type impurity density becomes approximately constant in the depth range between the lower surface 12b and the position 56. Moreover, as shown in FIG. 6, prior to the heating, the total amount of the n-type impurities is larger than the total amount of the p-type impurities in the depth range between the lower surface 12b and the position 56. Accordingly, as shown in FIG. 3, after the melting, the n-type impurity density becomes higher than the p-type impurity density in an entirety of the depth range between the lower surface 12b and the position 56. In other words, most of n-type impurities that exist in a high density in the deep portion of the semiconductor substrate 12 are diffused into the shallow portion of the semiconductor substrate 12, causing the shallow portion to be converted to be n-type. Moreover, the impurities are activated in the melted semiconductor region. Furthermore, a semiconductor region which is located in a range deeper than the position 56 and is not melted is also heated by the laser. Therefore, the impurities are activated even in the range deeper than the position 56. Accordingly, in each diode region 40, the n-type cathode region 48 exposed on the lower surface 12b is formed in the depth range between the lower surface 12b and the position 58.

As described above, by performing the laser irradiation step, the collector regions 30, the buffer regions 28, and the cathode regions 48 are formed.

After the laser irradiation step is performed, the lower electrode 16 is formed on the lower surface 12b of the semiconductor substrate 12. The semiconductor device 10 shown in FIG. 1 is thereby completed.

As described above, according to this method, there is no need to delimit implantation areas for p-type impurities and n-type impurities. Therefore, there is no need to form resist masks in the p-type impurity implantation step and the n-type impurity implantation step. Accordingly, a step related to formation and removal of the resist masks can be omitted. Moreover, it is easy to perform a laser irradiation so that the IGBT regions 20 and the diode regions 40 are irradiated at different energy densities, respectively. According to this method, the semiconductor device 10 can be manufactured efficiently. Moreover, in a case of using a resist mask, when the resist mask is removed after being used, there may be a case where residue of the resist mask remains on the surface of the semiconductor substrate. If the residue remains on the surface, there may be a case where a portion of the semiconductor substrate on which the residue remains is not sufficiently heated in the laser irradiation step, causing a failure to obtain desired electrical properties. According to the manufacturing method in the present embodiment, no resist mask is used, and hence such a problem does not occur.

Notably, in the above-mentioned embodiment, the areas irradiated with the laser on the forward path and the return path are partially overlapped so that the energy density in the diode regions 40 becomes higher than the energy density in the IGBT regions 20. However, various methods other than the method in the embodiment can be adopted for making energy densities different between irradiated areas. For example, an irradiation intensity (W/cm²) of the laser may be made higher in the diode regions 40 than in the IGBT regions 20. Alternatively, a speed at which the focus 90 of the laser is moved may be made slower in the diode regions 40 than in the IGBT regions 20. Lowering the speed at which the focus 90 of the laser is moved can lengthen laser irradiation time, and hence the energy density can be increased. Moreover, these methods may be combined.

Moreover, in the above-mentioned embodiment, the collector regions 30 are formed in the depth range between the lower surface 12b and the position 53. However, the depth range where the collector regions 30 are formed can be changed. As mentioned above, the position 54 in FIG. 6 is a position at which the total amount of the p-type impurities that exist in the depth range between the lower surface 12b and the position 54 coincides with the total amount of the n-type impurities that exist in the same depth range. Accordingly, in a depth range between a position shallower than the depth D4 and the lower surface 12b, the total amount of the p-type impurities is larger than the total amount of the n-type impurities. Accordingly, in the laser irradiation step, by diffusing the impurities in a depth range between the lower surface 12b and one of positions shallower than the depth D4, it is possible to form a p-type region exposed on the lower surface 12b.

Moreover, in the above-mentioned embodiment, the cathode regions 48 are formed in the depth range between the lower surface 12b and the position 58. However, the depth range where the cathode regions 48 are formed can be changed. In a depth range between a position deeper than the depth D4 and the lower surface 12b, the total amount of the n-type impurities is larger than the total amount of the p-type impurities. Accordingly, in the laser irradiation step, by diffusing the impurities in a depth range between the lower surface 12b and one of positions deeper than the depth D4, it is possible to form an n-type region exposed on the lower surface 12b.

Moreover, in the above-mentioned embodiment, a semiconductor region is melted in the depth range between the lower surface 12b and the position 52 in the IGBT regions 20. Moreover, a semiconductor region is also melted in the depth range between the lower surface 12b and the position 56 in the diode regions 40. However, a semiconductor region does not necessarily need to be melted. Even if a semiconductor region is not melted, impurities can be diffused in the semiconductor region in a solid state. However, it should be noted that, if the semiconductor region is melted, the impurities are more uniformly distributed in the melted semiconductor region. Accordingly, the collector regions 30 and the cathode regions 48 can be formed more stably. Moreover, if a semiconductor region is once melted and then solidified, a large number of crystal defects in the semiconductor region disappear. Accordingly, it is possible to form the collector regions 30 and the cathode regions 48 each having a low crystal defect density. Therefore, it is more preferable to melt a semiconductor region.

Notably, in the IGBT regions 20, it is preferable to melt a depth range between a position shallower than the position 53 (the position at which the p-type impurity density and the n-type impurity density coincide with each other prior to the heating) and the lower surface 12b. In this depth range, the p-type impurity density is higher than the n-type impurity density, and hence the collector regions 30 can be formed more reliably. Moreover, in the IGBT regions 20, it is preferable to melt a depth range between a position deeper than the position 51 (a peak position of the p-type impurity density prior to the heating) and the lower surface 12b. By melting the depth range that includes the peak position of the p-type impurity density as such, it is possible to form the collector regions 30 that have a high p-type impurity density on the lower surface 12b.

Moreover, in the diode regions 40, it is preferable to melt a depth range between a position deeper than the position 55 (a peak position of the n-type impurity density prior to the heating) and the lower surface 12b. By melting the depth range that includes the peak position of the n-type impurity density as such, it is possible to form the cathode regions 48 that have a high n-type impurity density on the lower surface 12b.

Moreover, in the above-mentioned embodiment, the n-type impurities and the p-type impurities are implanted to the lower surface 12b of the semiconductor substrate 12. Alternatively, an n-type semiconductor region may be formed by epitaxial growth and the like, and the p-type impurities may be implanted to that n-type semiconductor region. Moreover, a p-type semiconductor region may be formed by epitaxial growth and the like, and the n-type impurities may be implanted to that p-type semiconductor region.

Moreover, in the above-mentioned embodiment, a method of manufacturing an RC-IGBT has been described. However, in a semiconductor device that has no IGBT structure but has a diode structure, an n-type region (a cathode region) and a p-type region may be formed so as to be exposed on a lower surface of the diode. Even with such a diode, the effect of suppressing a reverse recovery loss, which is mentioned above, can be obtained. Moreover, when the n-type region and the p-type region exposed on the lower surface of the diode are formed, the manufacturing method in the above-mentioned embodiment can be used. Moreover, the art disclosed herein may be applied to a step of manufacturing other semiconductor devices having a p-type region and an n-type region exposed on a surface.

Relationships between constituent elements in the above-mentioned embodiment and constituent elements in the claims will be described. The lower surface 12b in the IGBT regions 20 in the embodiment is one example of a first area in the claims. The lower surface 12b in the diode regions 40 in the embodiment are one example of a second area in the claims. The position 52 in the embodiment is one example of a first position in the claims. The position 56 in the embodiment is one example of a second position in the claims. The collector regions 30 in the embodiment are one example of a first conductivity type region in the claims. The cathode regions 48 in the embodiment are one example of a second conductivity type region in the claims.

Preferable configurations of the embodiment described above will hereinafter be enumerated. Notably, each of the configurations enumerated below has utility independently.

In a configuration disclosed herein as an example, a semiconductor region in the first depth range on the first area is temporarily melted with the laser irradiation.

If the semiconductor region is temporarily melted and then solidified as such, impurities are uniformly dispersed in this semiconductor region and the impurity density becomes approximately constant. Moreover, if the semiconductor region is temporarily melted and then solidified, a large number of crystal defects disappear. Therefore, according to this method, it is possible to form the first conductivity type region having a relatively uniform impurity density and a low crystal defect density.

Notably, as described above, if the semiconductor region is temporarily melted and then solidified, the impurity density becomes approximately constant in that semiconductor region. Accordingly, by measuring the impurity density distribution in the semiconductor region, it is possible to determine whether or not the semiconductor region has been temporarily melted.

In a configuration disclosed herein as an example, a semiconductor region in the second depth range on the second area is temporarily melted with the laser irradiation.

According to this method, it is possible to form the second conductivity type region having a relatively uniform impurity density and a low crystal defect density.

In a configuration disclosed herein as an example, the first conductivity type is p-type, and the second conductivity type is n-type.

According to such a configuration, on the first area, an n-type region is formed at a position deeper than the p-type first conductivity type region (the region exposed on the surface). This n-type region can be utilized as a buffer region that stops extension of a depletion layer in an IGBT or a diode.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A method of manufacturing a semiconductor device, the method comprising:
implanting at least one of first impurities of a first conductivity type and second impurities of a second conductivity type to a processing area in a surface of a semiconductor substrate, wherein the processing area includes a first area in the surface and a second area in the surface, the implantation is performed so as to obtain, in a view of impurity distribution along a depth direction of the semiconductor substrate, a relationship that a total amount of the first impurities is larger than a total amount of the second impurities in a first depth range between the surface and a first position and a total amount of the second impurities is larger than a total amount of the first impurities in a second depth range between the surface and a second position, the first position is located at a first depth from the surface, the second position is located at a second depth from the surface, and the second depth is deeper than the first depth; and
irradiating the surface with a laser so that an energy density of the laser on the second area is larger than an energy density of the laser on the first area, wherein a first conductivity type region in which the first impurities exist in higher density than the second impurities is formed in the first depth range on the first area so as to be exposed on the surface, and a second conductivity type region in which the second impurities exist in higher density than the first impurities is formed in the second depth range on the second area so as to be exposed on the surface.

2. The method of claim 1, wherein a semiconductor region in the first depth range on the first area is temporarily melted in the irradiation with the laser.

3. The method of claim 1, wherein a semiconductor region in the second depth range on the second area is temporarily melted in the irradiation with the laser.

4. The method of claim 1, wherein
the first conductivity type is a p-type, and
the second conductivity type is an n-type.
